(19) United States
(12) Patent Application Publication
(10) Pub. No.: US 2006/0157701 A1
(43) Pub. Date: Jul. 20, 2006

(54) Integrated sensor chip unit

(76) Inventors: Robert Bauer, Moosach (DE); Jochen von Hagen, Kolbermmor (DE)

Correspondence Address: BRINKS HOFER GILSON & LIONE;INFINEON, PO BOX 10395, CHICAGO, IL, 60610, US

(21) Appl. No.: 11/329,981

(22) Filed: Jan. 10, 2006

Related U.S. Application Data
(63) Continuation of application No. PCT/EP04/51394, filed on Jul. 7, 2004.

(30) Foreign Application Priority Data
Jul. 19, 2003 (DE) 103 32 878.5

(51) Int. Cl. H01L 23/58

(52) U.S. Cl. 257/48

(57) ABSTRACT

The invention relates to a sensor module, in particular a measured-value pickup (2) for determining measurement data and a circuit arrangement (3) for enabling a wire-free power supply and interrogation of the measurement data. The measured-value pickup is formed as an integrable sensor (2), and the circuit arrangement is formed as an integrated semiconductor circuit module (3), the sensor (2) and the semiconductor circuit module (3) being mechanically and electrically conductively connected to one another to form an integrated sensor chip unit (1) using microsystems engineering means.

The present invention relates to a sensor module, in particular to a measured-value pickup for determining measurement data and a circuit arrangement for enabling a wire-free power supply and interrogation of the measurement data in accordance with the preamble of claim 1.

Sensors of this type are known. The German utility model DE 201 21 388 U1 discloses a sensor in which a deformable membrane and a counterelectrode are micro-patterned and form a capacitance of a resonant circuit. An evaluation circuit is not integrated into the sensor.

The German utility model DE 202 02 131 U1 describes a system for continuously monitoring biometric data of a living organism. It provides a sensor having a trans-ponder and an interrogation station separate from the evaluation unit. The sensor does not have an evaluation circuit in this case.

DE 43 41 903 A1 furthermore describes a device which is suitable for continuously measuring the pressure and/or the flow rate and/or the temperature and/or potentials and currents in bodies or organs of humans and animals. The device described therein communicates the measured values or measurement signals without cabling percutaneously (that is to say through the skin) to a receiver unit situated outside the body, which receiver unit processes and displays the measurement signals.

Furthermore, the American patent specification U.S. Pat. No. 5,711,861 discloses an electrochemical sensor whose signals are transmitted to an external receiver in wire-free fashion by means of a transmitter and are evaluated by means of a computer.

Sensors of this type which operate without cables and in which both the measured-value read-out and the power supply are effected in wire-free fashion are thus already known in principle

Since the known sensors do not comprise conditioning circuits, because they would then occupy excessively large volumes, disturbances can occur during signal transmission. For the weak signals of the measured-value pickups, it is clearly outside the body that amplification and conditioning become possible, because it is only here that the corresponding circuits are available. Implanting complex evaluation circuits in patients' bodies would be unpleasant and difficult to carry out on the patients on account of the large volumes.

The present invention is based on the object of providing a measured-value pickup which already contains evaluation electronics in order that the measurement signals generated can be transmitted in wire-free fashion after having already been conditioned. In this case, the determining size should be the sensor.

This object is achieved by means of a measured-value pickup having the features of claim 1. Advantageous refinements can be gathered from the dependent claims.

The advantages of the measured-value pickup according to the invention include its small size, its reliability and the possibility of transmitting already digitized measurement signals. As a result, the susceptibility to interference decreases and the reliability in obtaining measured values increases to the same extent.

A measured-value pickup—configured according to the present invention—for determining measurement data and a circuit arrangement for enabling a wire-free power supply and interrogation of the measurement data are particularly advantageous if the measured-value pickup is formed as an integrable sensor and if the circuit arrangement is embodied as an integrated semiconductor circuit module, the sensor and the semiconductor circuit module being mechanically and electrically conductively connected to one another to form an integrated sensor chip unit using microsystems engineering means.

A measured-value pickup is particularly advantageous if the microsystems engineering means comprise, for example, the “flip-chip technique” as method.

Advantageous measured-value pickups can be realized if the sensor is realized by a biometric sensor, for example a glucose sensor. A blood oxygen sensor or a light absorption sensor can also be used advantageously in the case of the invention.

It is likewise conceivable for the sensor to be realized by a pressure sensor, a thermo sensor or a chemical sensor.

It is furthermore advantageous if the semiconductor circuit module has components for power supply and a measured-value conditioning circuit, in particular with a digitization stage, for data exchange.

Further areas of use arise if the integrated sensor chip unit is surrounded by an encapsulation.

Such areas of use are for example implantations into human or animal bodies. Furthermore, it is possible for the integrated sensor chip unit to swim in bodily fluids on account of its encapsulation.

Moreover, it is advantageous for the power supply and the data exchange to be effected by means of a remotely acting receiving unit, particularly if the remote action is based on inductive coupling.

In general technology, an integrated sensor chip unit can be integrated very well in walls of a pipeline system or other containers.

Integrated sensor chip units can likewise advantageously be used for process monitoring in containers with liquids.

The invention will be explained in greater detail on the basis of exemplary embodiments in the drawings below.

In the figures:

FIG. 1 shows a highly schematic sensor chip according to the invention;

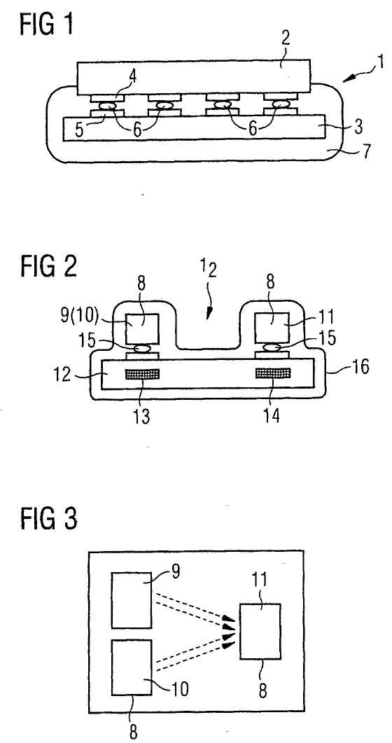

FIG. 2 shows a further sensor chip according to the invention in side view;

FIG. 3 shows the plan view of a sensor chip in accordance with FIG. 2 in highly schematic fashion;

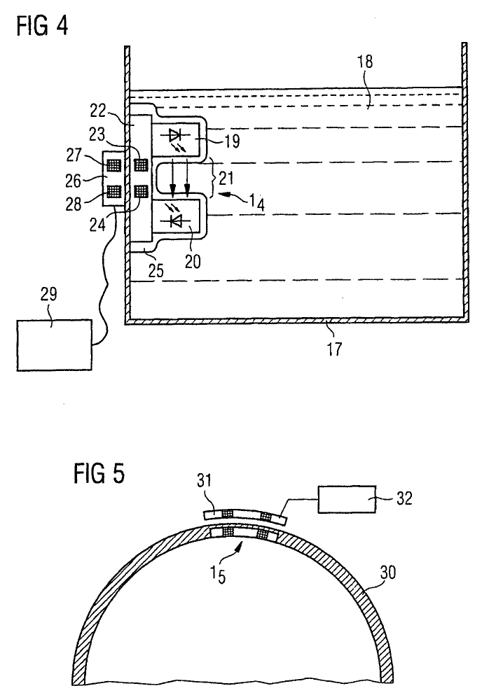

FIG. 4 shows a further exemplary embodiment of a sensor chip in side view and

FIG. 5 shows a further variant of an application of a sensor chip according to the invention.

FIG. 1 illustrates an integrated sensor chip unit 1 serving for determining the glucose content in the blood of a living organism. For measuring the glucose content in blood, sensors 2 of this type are already known in principle—as already explained, referenced by means of cited documents and described in the introduction. They are based, e.g. on capacitance measurements. A complex circuit arrangement is required in order to condition the signals generated in this way. Requisite electronics can be made very small by using integrated circuits and ultimately lead to an integrated circuit in the form of an integrated semiconductor circuit module 3. The sensor 2 and the integrated semiconductor circuit module 3 are connected to one another using microsystems engineering means. This connection is effected electrically and mechanically, thus giving rise to an integrated sensor chip unit 1 according to the invention.

The measured-value pickup 2 is embodied using so-called nanotechnology and, in the same way as the integrated semiconductor circuit module 3, requires only a very small volume.

A connection in the manner of a so-called flip-chip method is shown as an example of the connection of the measured-value pickup 2 to the integrated semiconductor circuit module 3.

This is a technology in which semiconductor chips on which small solder balls (bumps) are situated are mounted directly onto the circuit board without their own housing. In order to fix the placed component on the circuit board, only a flux is applied, which initially acts as an adhesive and evaporates again during the subsequent soldering process. The designation flip-chip stems from the fact that the chip lies with the small solder balls upward and has to be turned (flipped) prior to placement. This technique is explained for example on the Internet page of the company “Binder Elektronik GmbH” http://www.binderelektronic.de/.

However, other technologies of microsystems engineering can also be employed. A further method is so-called ball wedge bonding, by means of which gold wire bonding connections can be produced and the integrable components can thus be constructed using chip-on-board technology (COB).

There is furthermore the possibility of putting so-called gold stud bumps onto silicon carriers. These stud bump flip-chips can then be mounted by means of conductive or snap-cure adhesives. This is particularly ideal for small series.

The invention employs this microsystems engineering directly, then, such that a measured-value pickup (sensor 2), with the aid of this technology, is not connected on a circuit board, but rather directly to the integrated semiconductor circuit module 3 containing the entire evaluation electronics for the measured-value pickup (sensor 2). As a result of this further integration step, the volume of the integrated sensor chip unit can be significantly reduced even further.

In order to produce the connection, both the sensor 2 and the semiconductor circuit module 3 contain connection areas in the form of so-called “pads” 4 and 5, with the aid of which it is possible to produce an intimate metallic connection between the components—sensor 2 and semiconductor circuit module 3. For this purpose, solder balls 6 are in each case arranged between said pads 4 and 5. When joining together the sensor 2 and semiconductor circuit module 3 in accordance with microsystems engineering, said small solder balls 6 melt for example under the influence of heat and pressure, so that an intimate metallic connection is produced between the sensor 2 and semiconductor circuit module 3. Consequently, after the combining operation, the unit “measured-value pickup/integrated semiconductor circuit module” 2/3 forms an integrated sensor chip unit 1, which is provided with an encapsulation 7 so that it can be implanted into an animal or human body.

FIG. 2 illustrates a side view of a further exemplary embodiment of an integrated sensor chip unit 12 according to the invention and FIG. 3 reveals the associated plan view of this highly schematic exemplary embodiment.

A sensor 8 is shown there, which can be used to measure the concentration of the oxygen content in the blood of a living organism. The measured-value pickup (sensor 8) has at least two light-emitting diodes 9 and 10. The light-emitting diodes 9 and 10 emit light of different spectra; by way of example, one operates in the red region and the other in the infrared region. Furthermore, the measured-value pickup (sensor 8) carries a photodiode 11, which receives light emissions of the light-emitting diodes 9 and 10. Analogously to the exemplary embodiment in accordance with FIG. 1, the evaluation electronics are again situated in an integrated semiconductor circuit module 12 which advantageously also has elements such as, for example, coils 13 and 14 for power and data transmission. This integrated sensor chip unit 12 shown in FIGS. 2 and 3, comprising a measured-value pickup 8 and a semiconductor circuit module 12, is also—in a manner similar to the integrated sensor chip unit 1 in accordance with the exemplary embodiment shown in FIG. 1—joined together by means of small solder balls 15 using means of flip-chip technology known from microsystems engineering and is provided with an encapsulation 16, so that it has an extremely small size and can readily be implanted in a living organism.

In both exemplary embodiments, the semiconductor circuit module 3 and 12 contains coils for power and data transmission, so that the measurement data of the integrated sensor chip unit 1 and 1₂ can be interrogated contactlessly from outside the body of the living organism. This contactless transmission of measurement data is known per se, but becomes possible even more simply and primarily more reliably by virtue of the small size of the integrated sensor chip unit according to the invention since the conditioning circuit for the measurement data is already situated in the semiconductor circuit module 3 and 12 which according to the invention is part of the integrated sensor chip unit 1 and 1₂.

A further exemplary embodiment is illustrated in FIG. 4. A container 17 contains a liquid 18, the chemical reaction of which is to be monitored. In order to follow the progress of the process, it is necessary to determine the concentration of the substance and the distribution thereof in the container 17. The concentration can be determined with the aid of light absorption of the liquid 18. In order to determine the light absorption, an integrated sensor chip unit 1₄ has at least one light-emitting diode 19 with a specific wavelength. The emitted radiation of the light-emitting diode 19 is received by a photodiode 20. Situated between the emitting light-emitting diode 19 and the receiving photodiode 20 is an interspace in which the liquid 18 to be monitored circulates. The interspace may be referred to as absorption path 21 within which the circulating liquid 18 is measured.

The light-emitting diode 19 and the photodiode 20 are integrated, in the manner already described with regard to the other exemplary embodiments, with the aid of microsystems engineering on a semiconductor circuit module 22 containing the electronic conditioning circuit and also two coils 23 and 24 for the power supply and data exchange. The integrated semiconductor circuit module 22 drives inter alia the LEDs (light-emitting diode 19 and photodiode 20), conditions the measured values and digitizes them. Of the coils 23 and 24 integrated in the semiconductor circuit module 22, one—coil 23—serves for power transmission and the other—coil 23—serves for data exchange and programming of the semiconductor circuit module 22. The entire integrated sensor chip unit 1₄ is provided with encapsulation 25 so that it cannot be attacked by the substances of the liquid 18 situated in the container 17.

A plurality of the integrated sensor chip units 1₄ may be arranged at different locations of the inner wall of the container 17. One or more receiving units 26 may be fitted to the outer side of the container 17. The receiving units 26 operate in wire-free fashion and can read the integrated sensor chip units 1₄ in parallel or serially. For their part they contain two coils 27 and 28, of which one—coil 27—serves for power transmission and the second—coil 28—serves for data exchange. An evaluation device, for example a computer 29 is connected to the receiving unit 26. The container 17 must be composed of nonmetallic material at the installation locations for the integrated sensor chip units 1₄.

FIG. 5 illustrates a further exemplary embodiment, demonstrating the incorporation of an integrated sensor chip unit 1₅ according to the invention. A pipeline system 30 serves to supply compressed air or a process gas. Through an increase in the number of consumption points in the system, the pressure may be reduced or pressure losses occur due to leakages in the system. Searching for these often proves to be very difficult and costly since each consumption station has to be examined manually. The problem point in the system can be narrowed down more rapidly by the installation of a plurality of pressure sensors. The components correspond to those from the exemplary embodiments described above, although the integrated sensor chip unit 1₅ is formed as a pressure sensor with an integrated evaluation circuit in accordance with the exemplary embodiments described above. A receiving unit 31 with a computer as an evaluation device 32 can be guided along the pipeline system 30 in order to read out the measured values of the respective integrated sensor chip units 1₅.

As shown in the exemplary embodiment in accordance with FIG. 5, the integrated sensor chip units can be introduced in the pipe wall as early as during the production thereof. As a result, the costs of the pipes increase only to an insignificant extent since the production costs of the integrated sensor chip units are significantly less than the production costs that arise anyway for the pipes. However, separate fixing of the integrated sensor chip units on the inner walls of the pipes can also be realized advantageously. In all applications, the integrated sensor chip units can be arranged at specific distances in the pipe, so that the evaluation unit can be guided along the outer wall of the pipe in order progressively to successively read all the relevant integrated sensor chip units.

We claim:

1. An integrated sensor chip unit comprising:
a measured-value pickup operative to determine measurement data; and
a circuit arrangement operative to enable a wireless power supply and interrogation of the measurement data,
wherein the measured-value pickup is formed as an integratable sensor and the circuit arrangement is embodied as an integrated semiconductor circuit module, the sensor and the semiconductor circuit module mechanically and electrically conductively connected to one another using a microsystems engineering technology.

2. The integrated sensor chip unit of claim 1, wherein the semiconductor circuit module comprises a measured-value conditioning circuit.

3. The integrated sensor chip unit of claim 1, wherein the semiconductor circuit module comprises a measured-value conditioning circuit with a digitization stage.

4. The integrated sensor chip unit of claim 1, wherein the semiconductor circuit module comprises a remotely acting receiving unit operative to effect power supply and data exchange.

5. The integrated sensor chip unit of claim 1, wherein remote action of the remotely acting receiving unit comprises inductive coupling.

6. An integrated sensor chip unit comprising:
a measured-value pickup operative to determine measurement data;
a circuit arrangement operative to enable a wireless power supply and interrogation of the measurement data; and
an encapsulation surrounds the integrated sensor chip unit,
wherein the measured-value pickup is formed as an integratable sensor and the circuit arrangement is embodied as an integrated semiconductor circuit module, the sensor and the semiconductor circuit module mechanically and electrically conductively connected to one another using a microsystems engineering technology.

7. The integrated sensor chip unit of claim 6, wherein the encapsulation is comprised of materials that permit the integrated sensor chip unit to be implanted in human or animal bodies.

8. The integrated sensor chip unit of claim 6, wherein the encapsulation is comprised of materials that permit transport in bodily fluids.

9. The integrated sensor chip unit of claim 6, wherein the sensor chip unit is integratable in walls of a pipeline system.

10. The integrated sensor chip unit of claim 6, wherein the sensor comprises at least one of a biometric sensor, a glucose sensor, a blood oxygen sensor, a light absorption sensor, a pressure sensor, a thermo sensor, or a chemical sensor.

11. A method of fabricating an integrated sensor chip unit, the method comprising:
providing a measured-value pickup formed as an integratable sensor and operative to determine measurement data;
providing a circuit arrangement embodied as an integrated semiconductor circuit module and operative to enable a wireless power supply and interrogation of the measurement data; and
mechanically and electrically conductively connecting the sensor and the semiconductor circuit module to one another using a microsystems engineering technology.

12. The method of claim 11, wherein the microsystems engineering technology comprises flip-chip bonding.

13. The method of claim 11, wherein the semiconductor circuit module comprises a measured-value conditioning circuit.

14. The method of claim 11, wherein the semiconductor circuit module comprises a remotely acting receiving unit operative to effect power supply and data exchange.

15. The method of claim 11, wherein remote action of the remotely acting receiving unit comprises inductive coupling.

16. A method of fabricating an integrated sensor chip unit, the method comprising:
providing a measured-value pickup formed as an integratable sensor and operative to determine measurement data;
providing a circuit arrangement embodied as an integrated semiconductor circuit module and operative to enable a wireless power supply and interrogation of the measurement data;
mechanically and electrically conductively connecting the sensor and the semiconductor circuit module to one another using a microsystems engineering technology; and
encapsulating the integrated sensor chip unit in an encapsulation.

17. The method of claim 16, wherein the encapsulation is comprised of materials that permit the integrated sensor chip unit to be implanted in an animal body.

18. The method of claim 16, wherein the encapsulation is comprised of materials that permit transport in bodily fluids.

19. The method of claim 16, wherein the sensor chip unit is integratable in walls of a pipeline system.

20. An integrated sensor chip unit comprising:
means for determining measurement data; and
means for enabling a wireless power supply and interrogation of the measurement data that is mechanically and electrically conductively connected to the determining means using microsystems engineering means.

21. The integrated sensor chip unit of claim 20, wherein the enabling and interrogation means comprises means for digitizing the measurement data.

22. The integrated sensor chip unit of claim 20, wherein the enabling and interrogation means comprises means for effecting power supply and data exchange.

23. The integrated sensor chip unit of claim 20, wherein the means for effecting power supply and data exchange comprises means for inductive coupling.

24. The integrated sensor chip unit of claim 20, further comprising means for permitting the integrated sensor chip unit to be at least one of implanted in an animal body or transported in bodily fluids.

25. The integrated sensor chip unit of claim 20, further comprising means for permitting the sensor chip unit to be integrated in walls of a pipeline system.
